(19) United States
(12) Patent Application Publication
(10) Pub. No.: US 2007/0148841 A1
(43) Pub. Date: Jun. 28, 2007

(54) METHOD FOR FORMING TRANSISTOR IN SEMICONDUCTOR DEVICE

(76) Inventor: Pyoung On Cho, Seoul (KR)

Correspondence Address: SHERR & NOURSE, PLLC, 620 HERNDON PARKWAY, SUITE 200, HERNDON, VA, 20170, US

(21) Appl. No.: 11/616,806

(22) Filed: Dec. 27, 2006

(30) Foreign Application Priority Data
Dec. 28, 2005 (KR) 10-2005-0131625

(51) Int. Cl. H01L 21/336

(52) U.S. Cl. 438/197; 438/305; 438/301

(57) ABSTRACT

A method for forming a transistor in a semiconductor device with an elongated channel region. The method includes the steps of forming a polysilicon layer on a semiconductor substrate and patterning the polysilicon layer to form a dummy substrate, and forming a gate oxidation layer and a gate electrode on the semiconductor substrate having the dummy substrate.

The present application claims priority under 35 U.S.C. 119 and 35 U.S.C. 365 to Korean Patent Application No. 10-2005-0131625 (filed on Dec. 28, 2005), which is hereby incorporated by reference in its entirety.

### BACKGROUND

In general, a metal oxide semiconductor (MOS) transistor is a type of field effect transistor. It has a structure in which source and drain regions are formed on a semiconductor substrate, with a gate oxidation layer and a gate formed over the source and drain regions. Particular MOS transistors may have a low concentration of implanted ions in a lightly doped drain (LDD) region, within the source and drain regions.

The structure of a related MOS transistor will be described below with reference to FIG. 1.

In the MOS transistor, an isolation layer 12 is defined, and an initial oxidation layer is grown on a P- or N-type single crystal semiconductor substrate 10. A well 11 is formed into which P- or N-type impurities are implanted, and a gate oxidation layer 14a is formed above the well. A polysilicon layer is formed on the gate oxidation layer 14a, and then a gate electrode 14b is formed by a lithography process. Low-concentration diffusion regions 16a are formed by implanting low-concentration impurity ions using the gate electrode 14b as a mask, and then performing heat treatment. Then, spacer layers 15 are formed on sidewalls of the gate electrode 14b, and high-concentration diffusion regions 16b are formed by implanting high-concentration impurity ions using the spacer layers 15 as masks, and then performing heat treatment.

Therefore, each of the source and drain regions 16 has an LDD structure of the low- and high-concentration diffusion regions 16a and 16b.

The transistor as described above has a channel region formed between the source and drain regions 16. To form a transistor with greater width in the channel region, the size of the semiconductor device must be increased.

### SUMMARY

Embodiments relate to a method for forming a transistor in a semiconductor device with a wider channel region.

Additional advantages, objects, and features of the embodiments will be set forth in part in the description which follows and in part will become apparent to those having ordinary skill in the art upon examination of the following or may be learned from practical experience with the embodiments. The objectives and other advantages of the embodiments may be realized and attained by the structure particularly pointed out in the written description and claims hereof as well as the appended drawings.

The method includes the steps of forming a polysilicon layer on a semiconductor substrate and patterning the polysilicon layer to form a dummy substrate, and forming a gate oxidation layer and a gate electrode on the semiconductor substrate having the dummy substrate.

Here, the dummy substrate may be formed of the same material as the semiconductor substrate.

The method may further include implanting ions over the top surface of the semiconductor substrate to form lightly doped regions adjacent the gate. Spacers are formed along the sidewalls of the gate and oxide regions. Ions are implanted over the top surface of the semiconductor substrate, using the gate and spacers as a mask, thereby forming source and drain regions.

It is to be understood that both the foregoing general description and the following detailed description of the embodiments are exemplary and explanatory and are intended to provide further explanation of the claims.

### BRIEF DESCRIPTION OF DRAWINGS

FIG. 1 is a sectional view illustrating a related transistor in a semiconductor device; and

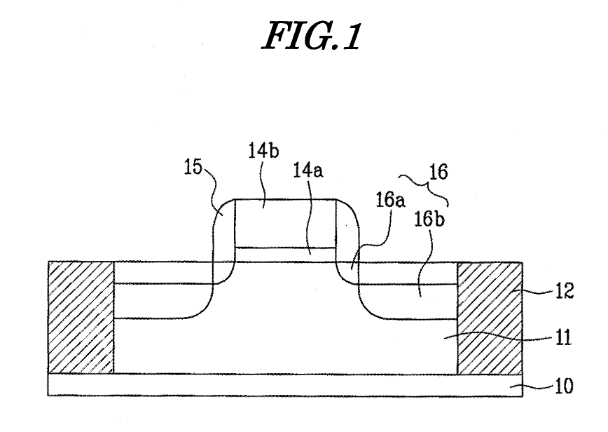

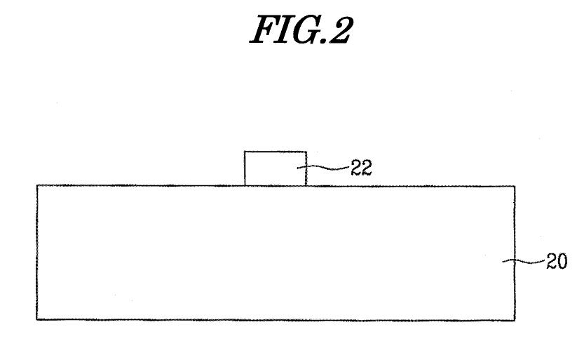

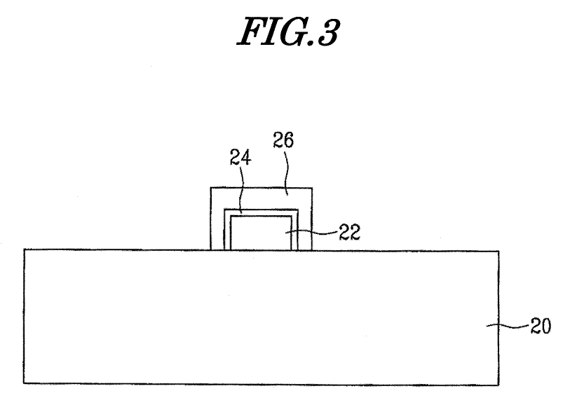

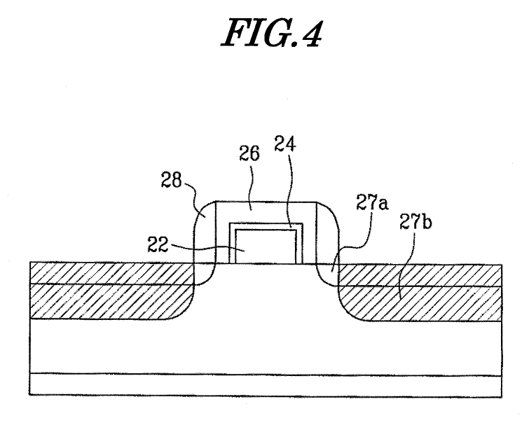

Example FIGS. 2, 3, and 4 are sectional views illustrating a method for forming a transistor in a semiconductor device in accordance with embodiments.

### DETAILED DESCRIPTION

Hereinafter, embodiments will be described in detail with reference to the following drawings. The embodiments should not be construed as being limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that, when a layer is referred to as being “on” another layer or substrate, it can be directly formed on the other layer or substrate, or one or more intervening layers may be present. Like numbers refer to like elements throughout the drawings.

FIGS. 2, 3, and 4 are sectional views illustrating a method for forming a transistor in a semiconductor device in accordance with embodiments.

As illustrated in FIG. 2, a well region (not shown) is formed on a predetermined region in a semiconductor substrate 20.

The process of forming the well region is as follows. First, a screen oxidation layer is formed on the semiconductor substrate. Then, a first ion implantation mask, exposing a well defined region, is formed on the semiconductor substrate 20. An ion implantation layer is formed in the well defined region by implanting ions into the top surface of the semiconductor substrate. The first ion implantation mask is removed. A heat treatment process is performed on the semiconductor substrate, so that the ions in the ion implantation layer are diffused. The formation of the well region is thereby completed.

A polysilicon layer for a dummy substrate is formed over the well region on the semiconductor substrate. A photoresist layer is applied to the polysilicon layer, and is selectively patterned using a photolithography process. A mask pattern is thereby formed, and the polysilicon layer is etched using the mask pattern, and the dummy substrate 22 remains at a predetermined region of the semiconductor substrate.

As illustrated in FIG. 3, an insulating layer, for use as a gate oxide, and a polysilicon layer, for use as a gate, are subsequently formed on the top surface the substrate 20, including the dummy substrate 22. Then, a photoresist layer is deposited over the polysilicon layer, and is subjected to a photolithography process and an etching process, thereby forming a mask pattern. The mask patterning process removes the portions of the photoresist which are over regions to be etched in the subsequent step. Then, an insulating layer, for use as a gate oxide, and a polysilicon layer, for use as a gate, are etched using the mask pattern. Thus, the gate oxide layer 24 and the gate 26 are formed to surround the dummy substrate 22.

Next, as illustrated in FIG. 4, an ion implantation is performed over the top surface of the semiconductor substrate 20 having the gate oxidation layer 24 and the gate 26, using a gate as a mask, to form lightly doped regions 27a. Thereafter, spacers 28 are formed, providing a mask for implants for source and drain regions 27b. Therefore, the process of forming the transistor is completed.

According to embodiments, a channel region is formed in the semiconductor substrate, including the dummy substrate between the source region and the drain region, so that the transistor has a longer channel region without increasing the footprint of the transistor over the substrate. In other words, a longer channel region is attained without increasing the area on the substrate used to form the transistor.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed:

1. A method of forming a transistor in a semiconductor device, the method comprising:
forming a conductive layer on a semiconductor substrate, and patterning the conductive layer to form a dummy substrate; and
forming a gate oxidation layer and a gate electrode on the semiconductor substrate having the dummy substrate.

2. The method of claim 1, wherein the dummy substrate is formed of a polysilicon layer that is the same material as the semiconductor substrate.

3. The method of claim 1, further comprising:
implanting ions on a top surface of the semiconductor substrate having the gate electrode after the gate electrode is formed, and thereby forming source and drain regions.

4. A method of forming a transistor in a semiconductor device, the method comprising:
forming a polysilicon layer on a semiconductor substrate, and patterning the polysilicon layer to form a dummy substrate; and
forming a gate oxidation layer and a gate electrode over the semiconductor substrate having the dummy substrate.

5. The method of claim 4, further comprising:
implanting ions over the top surface of the semiconductor substrate to form lightly doped regions adjacent the gate;
forming spacers along the sidewalls of the gate and oxide regions;
implanting ions on a top surface of the semiconductor substrate, using the gate and spacers as a mask, thereby forming source and drain regions.
